(19) United States
(12) Patent Application Publication
(10) Pub. No.: US 2025/0073850 A1
(43) Pub. Date: Mar. 6, 2025

(54) GAS AMPLIFIER FOR CMP COOLING

(71) Applicant: Applied Materials, Inc., Santa Clara, CA (US)

(72) Inventors: Haosheng WU, Fremont, CA (US); Shou-Sung CHANG, Mountain View, CA (US); Priscilla DIEP, San Jose, CA (US); Hui CHEN, San Jose, CA (US); Chih Chung CHOU, San Jose, CA (US); Jeonghoon OH, Saratoga, CA (US); Jianshe TANG, San Jose, CA (US); Brian J. BROWN, Palo Alto, CA (US)

(73) Assignee: Applied Materials, Inc., Santa Clara, CA (US)

(21) Appl. No.: 18/811,633

(22) Filed: Aug. 21, 2024

Related U.S. Application Data
(60) Provisional application No. 63/579,121, filed on Aug. 28, 2023.

(51) Int. Cl. B24B 53/017; H01L 21/306

(52) U.S. Cl. CPC B24B 53/017; H01L 21/30625

(57) ABSTRACT

A chemical mechanical polishing chamber may include a platen disposed within the chemical mechanical polishing chamber, the platen configured to support a polishing pad. The chamber may also include a slurry delivery arm configured to deliver a slurry to the polishing pad during a chemical mechanical polishing process. The chamber may include an arm may include one or more brackets, mechanically attached to an internal side of the chemical mechanical polishing chamber and positioned over the platen. The chamber may include a plurality of nozzles configured to deliver a gas to the polishing pad, the plurality of nozzles mechanically attached to the one or more brackets of the arm, each of the plurality of nozzles oriented such that an air gap is disposed between adjacent nozzles of the plurality of nozzles such that air may be pulled from the air gap and propelled with the gas towards the polishing pad.

### TECHNICAL FIELD

The present technology relates to semiconductor systems, processes, and equipment. More specifically, the present technology relates to the polishing of films deposited on a substrate.

### BACKGROUND

An integrated circuit is typically formed on a substrate by the sequential deposition of conductive, semiconductive, and/or insulative layers on a silicon wafer. A variety of fabrication processes use the planarization of a layer on the substrate between processing steps. For example, for certain applications, e.g., polishing of a metal layer to form vias, plugs, and/or lines in the trenches of a patterned layer, an overlying layer is planarized until the top surface of a patterned layer is exposed. In other applications, e.g., planarization of a dielectric layer for photolithography, an overlying layer is polished until a desired thickness remains over the underlying layer.

Chemical mechanical polishing (CMP) is one common method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. The abrasive polishing slurry is typically supplied to the surface of the polishing pad.

During polishing operations, it is desirable to cool the substrate and/or the polishing pad to decrease thermal effects on the substrate. To cool the substrate, cooling systems may traditionally utilize nozzles to deliver a gas to the substrate. The nozzles may be disposed within a sealed arm. The gas may be provided to the nozzles via a manifold or other suitable structure. However, because the nozzles may be disposed within the sealed arm, the cooling system may not perform optimally for certain applications (i.e., the substrate may not be cooled enough or quickly enough).

Thus, there is a need for improved systems and methods that can be used to improve cooling in chemical mechanical polishing systems. These and other needs are addressed by the present technology.

### SUMMARY

A chemical mechanical polishing chamber (“chamber”) may include a platen disposed within the chemical mechanical polishing chamber, the platen configured to support a polishing pad. The chamber may also include a slurry delivery arm configured to deliver a slurry to the polishing pad during a chemical mechanical polishing process. The chamber may include an arm may include one or more brackets, mechanically attached to an internal side of the chemical mechanical polishing chamber and positioned over the platen. The chamber may include a plurality of nozzles configured to deliver a gas to the polishing pad, the plurality of nozzles mechanically attached to the one or more brackets of the arm, each of the plurality of nozzles oriented such that an air gap is disposed between adjacent nozzles of the plurality of nozzles such that air may be pulled from the air gap and propelled with the gas towards the polishing pad.

In some embodiments, the chemical mechanical polishing chamber may include a manifold disposed above the plurality of nozzles configured to provide air to the plurality of nozzles. The gas may include nitrogen. The chemical mechanical polishing chamber may include a manifold fluidly connected to each of the plurality of nozzles, the manifold configured to deliver a pressurized gas. In some embodiments, each of the plurality of nozzles may include a chamfer configured to direct the gas into a respective nozzle to increase a volume of gas delivered to the polishing pad via the respective nozzle.

A gas amplifying nozzle for a chemical mechanical polishing chamber may include a main chamber. The gas amplifying nozzle may also include a first opening at a top of the nozzle, configured to allow air to enter the main chamber. The gas amplifying nozzle may include a chamfer attached to the top end of the gas amplifying nozzle, configured to direct air into the main chamber of the gas amplifying nozzle. The gas amplifying nozzle may include a side chamber configured to receive a pressurized gas and may include an opening to provide the pressurized gas to the main chamber of the gas amplifying nozzle. The gas amplifying nozzle may include a second opening at a bottom of the nozzle to direct an outflow may include the air and pressurized gas from the main chamber to a platen to cool a polishing pad.

In some embodiments, the pressurized gas may be received via a manifold fluidly connected to the gas nozzle. In some embodiments, the outflow may include water. The air surrounding the gas nozzle may be entrained in the outflow directed to the polishing pad. The pressurized gas may include nitrogen. The second opening may include a diameter of about 1 cm. The air may be directed into the chamfer, at least in part by a fan. The pressurized gas may increase a velocity of the outflow of the air and the pressurized gas from the main chamber.

A method may include moving a substrate via a carrier onto a polishing pad supported by a platen within a chemical mechanical polishing chamber. The method may include providing a slurry to the polishing pad and/or the substrate. The slurry may include one or more compounds to perform chemical mechanical processing. The method may include rotating the platen such that the slurry and the polishing pad removes material from the substrate. The method may include providing a first fluid to a nozzle. The method may include providing a second fluid to the nozzle such that the second fluid combines with the first fluid and a gas surrounding the nozzle to form an outflow, the outflow directed towards the substrate and/or polishing pad.

In some embodiments, the outflow may include an atomized fluid may such as water. The outflow may cool the substrate and/or the polishing pad to less than or about 37° C. The substrate and/or the polishing pad may be cooled to less than or about 37° C. in less than or about 10 seconds. The second fluid may include pressurized nitrogen. At least a portion of the first fluid may be drawn into the nozzle from the chemical mechanical polishing chamber via a chamfer. The substrate and/or the polishing pad may be cooled to less than or about 30° C.

### BRIEF DESCRIPTION OF THE DRAWINGS

A further understanding of the nature and advantages of the disclosed technology may be realized by reference to the remaining portions of the specification and the drawings.

FIG. 1 illustrates a chemical mechanical polishing chamber, according to certain embodiments.

FIG. 2 illustrates a chemical mechanical polishing chamber including a gas amplifier for cooling a polishing pad, according to certain embodiments.

FIG. 3 illustrates a gas amplifying nozzle, according to certain embodiments.

FIG. 4 illustrates a graph of a temperature versus time of a polishing pad, according to certain embodiments.

FIG. 5 illustrates a flowchart of a method for cooling a polishing pad during a chemical mechanical polishing process, according to certain embodiments.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description applies to any one of the similar components having the same first reference label irrespective of the letter.

### DETAILED DESCRIPTION

In traditional chemical mechanical polishing (CMP) operations, a gas is provided to a substrate and/or polishing pad to cool the substrate within a chamber during the CMP operations. The gas may be provided through nozzles disposed within a sealed arm. Because the nozzles are disposed within the sealed arm, the gas that each nozzle delivers may be limited to an amount of gas that may be provided from within the arm. For example, compressed nitrogen may be delivered via a manifold to the nozzles. The nozzles may then direct the compressed nitrogen to the substrate to cool the substrate.

In the system described above, the amount of gas able to be delivered to the substrate may be limited by the amount of gas delivered to the nozzles. Therefore, the amount of cooling able to be provided to the substrate may also be limited. However, the chamber may contain a gas such as air. If the air within the chamber is also directed towards the substrate during CMP operations, cooling performance may be enhanced. Because the cooling performance is enhanced, more consistent products may be manufactured using the substrate, as there may be less thermal strain on the substrate (and products made therefrom).

In one possible solution, a chemical mechanical processing chamber may include a plurality of nozzles. The plurality of nozzles may be attached to an arm including one or more brackets. The arm may be open, allowing the air within the chamber to flow in gaps defined between each of the plurality of nozzles. Furthermore, the nozzles may be configured to draw in air from the top of the chamber. When a pressurized gas is provided to each of the nozzles, the pressurized gas may (at least in part) help to draw in air from the top of the nozzle (e.g., via a chamfer). The pressurized gas and the air may combine within the nozzle and be directed towards the substrate as an outflow. A velocity of the outflow may create a low pressure zone at the edges of the outflow. The air in the gaps between each of the plurality of nozzles may then become entrained in the outflow. The amount of gas delivered to the substrate, then, may be increased two fold or more as compared to more traditional cooling systems. The cooling performance may therefore be increased, and the substrate may experience less thermal strain.

Although the remaining disclosure will routinely identify specific cooling mechanisms utilizing the disclosed technology, it will be readily understood that the systems and methods are equally applicable to a variety of other semiconductor processing operations and systems. Accordingly, the technology should not be considered to be so limited as for use with the described polishing systems or processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems, along with any number of modifications, some of which will be noted below.

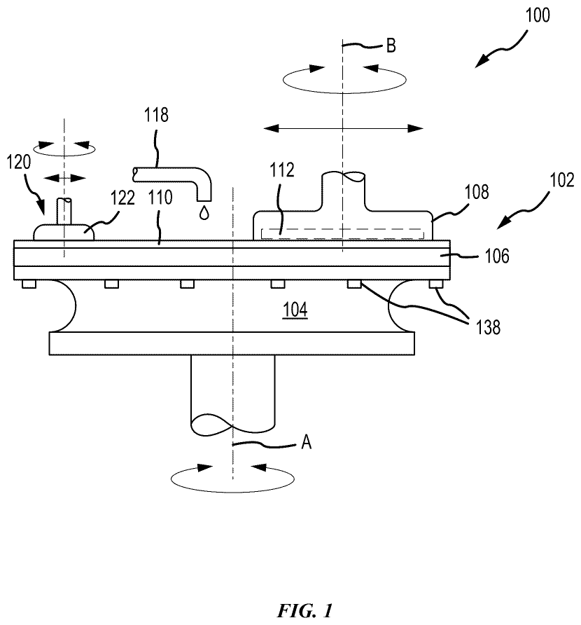

FIG. 1 illustrates a chemical mechanical polishing system 100, according to certain embodiments. Polishing system 100 includes a platen assembly 102, which includes a lower platen 104 and an upper platen 106. Lower platen 104 may define an interior volume or cavity through which connections can be made, as well as in which may be included end-point detection equipment or other sensors or devices, such as eddy current sensors, optical sensors, or other components for monitoring polishing operations or components. For example, and as described further below, fluid couplings may be formed with lines extending through the lower platen 104, which may access the upper platen 106 through a backside of the upper platen. Platen assembly 102 may support a polishing pad 110 mounted on a first surface of the upper platen. A substrate carrier 108, or carrier head, may be disposed above the polishing pad 110 and may face the polishing pad 110. The platen assembly 102 may be rotatable about an axis A, while the substrate carrier 108 may be rotatable about an axis B. The substrate carrier may also be configured to sweep back and forth from an inner radius to an outer radius along the platen assembly, which may, in part, reduce uneven wear of the surface of the polishing pad 110. The polishing system 100 may also include a fluid delivery arm 118 positioned above the polishing pad 110, which may be used to deliver polishing fluids, such as a polishing slurry, onto the polishing pad 110. Additionally, a pad conditioning assembly 120 may be disposed above the polishing pad 110 and may face the polishing pad 110.

In some embodiments of performing a chemical-mechanical polishing process, the rotating and/or sweeping substrate carrier 108 may exert a downforce against a substrate 112, which is shown in phantom and may be disposed within or coupled with the substrate carrier. The downward force applied may depress a material surface of the substrate 112 against the polishing pad 110 as the polishing pad 110 rotates about a central axis of the platen assembly. The interaction of the substrate 112 against the polishing pad 110 may occur in the presence of one or more polishing fluids delivered by the fluid delivery arm 118. A typical polishing fluid may include a slurry formed of an aqueous solution in which abrasive particles may be suspended. Often, the polishing fluid contains a pH adjuster and other chemically active components, such as an oxidizing agent, which may enable chemical mechanical polishing of the material surface of the substrate 112.

The pad conditioning assembly 120 may be operated to apply a fixed abrasive conditioning disk 122 against the surface of the polishing pad 110, which may be rotated as previously noted. The conditioning disk may be operated against the pad prior to, subsequent, or during polishing of the substrate 112. Conditioning the polishing pad 110 with the conditioning disk 122 may maintain the polishing pad 110 in a desired condition by abrading, rejuvenating, and removing polish byproducts and other debris from the polishing surface of the polishing pad 110. Upper platen 106 may be disposed on a mounting surface of the lower platen 104 and may be coupled with the lower platen 104 using a plurality of fasteners 138, such as extending through an annular flange-shaped portion of the lower platen 104.

The polishing platen assembly 102, and thus the upper platen 106, may be suitably sized for any desired polishing system and may be sized for a substrate of any diameter, including 200 mm, 300 mm, 450 mm, or greater. For example, a polishing platen assembly configured to polish 300 mm diameter substrates, may be characterized by a diameter of more than about 300 mm, such as between about 500 mm and about 1000 mm, or more than about 500 mm. The platen may be adjusted in diameter to accommodate substrates characterized by a larger or smaller diameter, or for an upper platen 106 sized for concurrent polishing of multiple substrates. The upper platen 106 may be characterized by a thickness of between about 20 mm and about 150 mm and may be characterized by a thickness of less than or about 100 mm, such as less than or about 80 mm, less than or about 60 mm, less than or about 40 mm, or less. In some embodiments, a ratio of a diameter to a thickness of the upper platen 106 may be greater than or about 3:1, greater than or about 5:1, greater than or about 10:1, greater than or about 15:1, greater than or about 20:1, greater than or about 25:1, greater than or about 30:1, greater than or about 40:1, greater than or about 50:1, or more.

The upper platen and/or the lower platen may be formed of a suitably rigid, lightweight, and polishing fluid corrosion-resistant material, such as aluminum, an aluminum alloy, or stainless steel, although any number of materials may be used. Polishing pad 110 may be formed of any number of materials, including polymeric materials, such as polyurethane, a polycarbonate, fluoropolymers, polytetrafluoroethylene polyphenylene sulfide, or combinations of any of these or other materials. Additional materials may be or include open or closed cell foamed polymers, elastomers, felt, impregnated felt, plastics, or any other materials that may be compatible with the processing chemistries. It is to be understood that polishing system 100 is included to provide suitable reference to components discussed below, which may be incorporated in system 100, although the description of polishing system 100 is not intended to limit the present technology in any way, as embodiments of the present technology may be incorporated in any number of polishing systems that may benefit from the components and/or capabilities as described further below.

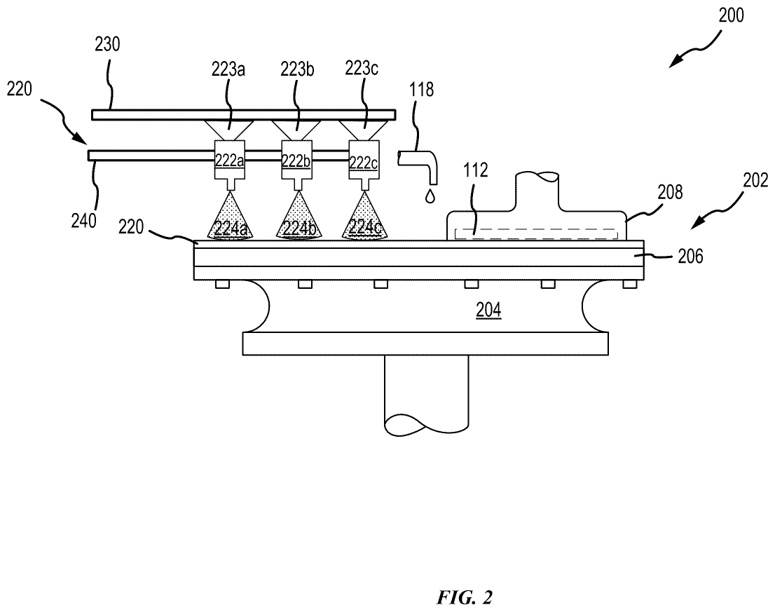

FIG. 2 illustrates a chemical mechanical polishing chamber 200 including a gas amplifier for cooling a polishing pad 210, according to certain embodiments. The chemical mechanical polishing chamber (sometimes, “chamber”) 200 may be similar to polishing system 100 in FIG. 1, including similar components and functionalities. Therefore, corresponding numbers may include similar descriptions as described above. The chamber 200 may include a platen assembly 202 including a lower platen 204 and an upper platen 206. The platen assembly 202 may include a polishing pad 210 mounted on a first surface of the upper platen. A substrate carrier 108, or carrier head, may be disposed above polishing pad 210 and may face the polishing pad 210. The chamber 200 may also include a slurry delivery arm 218 positioned above the polishing pad 210, and which may be used to deliver polishing fluids, such as a polishing slurry, onto the polishing pad 210. The polishing pad 210 may then polish a substrate 212.

The chamber 200 may also include a gas cooling assembly 220 for cooling the polishing pad 210 during a chemical mechanical polishing process. The gas cooling assembly may include one or more nozzles 222a-c, each connected to a respective chamfer 223a-c. Each of the nozzles 222a-c may provide a respective outflow 224a-c to the polishing pad 210 such that the polishing pad 210 is cooled during the chemical mechanical polishing process. The nozzles 222a-c may be positioned above the polishing pad 210 and supported by an arm 240. The arm 240 may be attached to an internal side of the chamber 200. In some embodiments, the arm 240 may extend along a single side of each of the nozzles 222a-c (e.g., a back side of the nozzles 222a-c). The nozzles 222a-c may therefore be attached to the arm 140 at a single point. In other embodiments, the arm 240 may extend along opposite sides of the nozzles 222a-c, such that the nozzles 222a-c are connected to the arm 240 at two points. In either case, air gaps may be defined between adjacent nozzles 222a-c that allow a gas within the chemical mechanical polishing system (sometimes “chamber”) 200 to flow freely between the nozzles 222a-c.

The arm 140 may also include a manifold to deliver a pressurized gas to each of the nozzles 222a-c. The manifold may therefore be fluidly connected to each of the nozzles 222a-c such that the pressurized gas may flow through each nozzle 222a-c into the respective outflow 224a-c. In some embodiments, the pressurized gas may include nitrogen. The manifold may deliver the pressurized gas to each of the nozzles 222a-c at a pressure of 2 ATM. In some embodiments, the manifold may deliver a particular volume of nitrogen at a particular rate.

The chamfers 223a-c may draw gas from within the chemical mechanical polishing chamber 200 into a respective nozzle 222a-c. For example, the chemical mechanical processing chamber 200 may be filled with air or other gas. The chamfers 223a-c may then draw the gas from within the chemical mechanical processing chamber 200 into a respective nozzle 222a-c. The gas may flow from the chamfers 223a-c to a main chamber of the nozzles 222a-c. The gas (e.g., air) may combine with the pressurized gas to form the outflow 224a-c in the main chamber. The pressurized gas may be moving faster than the air drawn in by the chamfers 223a-c, thus increasing a the velocity of the outflow 224a-c.

Each of the nozzles 222a-c may include a bottom aperture, directed towards the polishing pad 210. The opening at the bottom may be characterized by a radius, smaller than a radius of a the main chamber of the nozzle 222a-c. For example, the bottom aperture may be between 5 mm and 20 mm, inclusive. The main chamber of each of the nozzles 222a-c may include a radius of between 50 mm and 100 mm, inclusive. Thus, as the outflow 224a-c flows from the main chamber through the opening at the bottom of the nozzles 222a-c, the outflow 224a-c may be moving at a higher velocity than inside the main chamber.

The outflow 224a-c may be provided as an atomized fluid. The atomized fluid may include the gas, the pressurized gas, water, and any other suitable liquid. The outflow 224a-c may cool the polishing pad 210 and/or the substrate 212 to a temperature of less than or about 45° C., less than or about 40° C., less than or about 35° C., and less than or about 30° C. The temperature may be reached within a time range of less than or about 15 seconds, less than or about 12 seconds, and less than or about 9 seconds.

In some embodiments, the gas may be provided to the chamfers 223a-c via a second arm 130. The second arm 130 may provide air or another gas from outside the chamber 200 to each of the chamfers 223a-c. The second arm 130 may include a fan or other device to provide a direction and velocity to the gas within the second arm 130. Additionally or alternatively, the arm 130 may draw the gas from within the chamber 200 and provide the gas to the chamfers 223a-c.

In some embodiments, the nozzles 222a-c may not draw the gas in through the chamfers 223a-c. Instead, the nozzles 222a-c may only provide the pressurized gas from the manifold. As the pressurized gas exits the nozzles 222a-c, the gas surrounding the nozzles 222a-c (e.g., in gaps between each of the nozzles 222a-c) may become entrained with the pressurized gas to form the outflow 224a-c. The outflow 224a-c therefore may include a mix of the pressurized gas with some particles of the gas mixed throughout the outflow 224a-c. The outflow 224a-c may also include another atomized fluid, such as water.

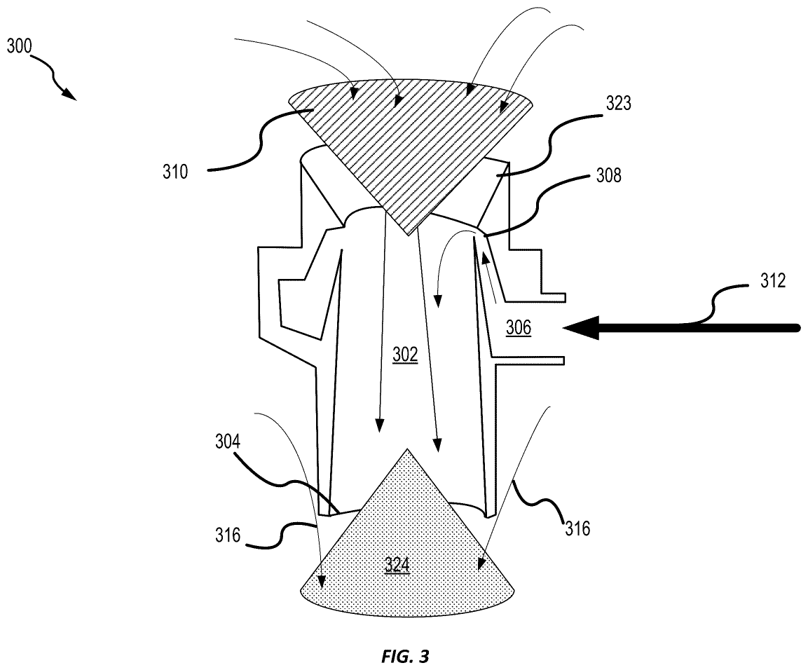

FIG. 3 illustrates a gas amplifying nozzle (“nozzle”) 300, according to certain embodiments. The nozzle 300 may be similar to at least some of the nozzles 222a-c in FIG. 2. In some embodiments, some of the nozzles 222a-c may be similar to the nozzle 300, whereas other nozzles 222a-c may include some or none of the components of the nozzle 300. In other embodiments, all of the nozzles 222a-c may be similar to the nozzle 300.

The nozzle 300 may include a main chamber 302, an outflow opening 304, a side chamber 306, and a chamfer 323. The side chamber 306 may be configured to receive a pressurized gas 312 and provide the pressurized gas 312 into the main chamber 302 via a small opening 308. The side chamber 306 may be fluidly connected to a manifold or similar structure capable of delivering the pressurized gas 312 to the nozzle 300. The pressurized gas 312 may include nitrogen, air, atomized water, and/or other suitable gasses. The small opening 308 may be characterized by a smaller radius than that of the side chamber 306. Therefore, when the pressurized gas 312 enters the main chamber 302 from the side chamber 306, the pressurized gas 312 may increase in velocity.

The chamfer 323 may intake a surrounding gas 310 from within a chemical mechanical polishing system (or “chamber”) such as the chamber 200. The surrounding gas 310 may be air or any other gas found within a chemical mechanical polishing chamber. In some embodiments, the chamfer 323 may passively direct the surrounding gas 310 into the main chamber of the nozzle 300. For example, the chamfer 323 may be characterized by a wider opening for drawing in the surrounding gas 310, and a narrower opening leading to the main chamber 302. The chamfer 323 may therefore direct the surrounding gas 310 from the chemical mechanical polishing chamber into the main chamber 302. The surrounding gas 310 may be (relatively) stagnant. Because the chamfer 323 is wider at a top end of the chamfer 323, the surrounding gas 310 may be directed into the chamfer 323. At the same time, the increased velocity of the pressurized gas 312 within the main chamber 302 may produce a relative low pressure area within the main chamber 302, above the small opening 308. The relative low pressure area may therefore further cause the surrounding gas 310 to flow from the chamfer 323 into the main chamber 302.

In other embodiments, the surrounding gas 310 may be actively directed into the chamfer 323 and/or the main chamber 302. For example, the chemical mechanical processing chamber may include a fan or other device for directing the surrounding gas 310 to the chamfer 323. Additionally or alternatively, the chamfer 323 may be fluidly connected to a second manifold or other delivery system for directing the surrounding gas 310 to the chamfer 323. One of ordinary skill in the art would recognize many different possibilities.

In the main chamber 302, the surrounding gas 310 and the pressurized gas 312 may combine to form outflow 324. The outflow 324 may be directed towards a substrate and/or polishing pad via the outflow opening 304. In some embodiments, the outflow opening 304 maybe configured to increase a velocity of the outflow 324. For example, the outflow opening 304 may be narrower than the main chamber 302 (e.g., 0.5 cm, 1 cm, 2 cm, etc.) The outflow opening 304 may also include an atomizer, configured to combine the surrounding gas 310, the pressurized gas 312, and/or another fluid (e.g.) water into an atomized mist as the outflow 324.

As described in FIG. 2, the nozzle 300 may be arranged on an arm (such as the arm 240) such that a gap is present between any two nozzles on the arm. The gap may be filled with the a second gas 316. The second gas 316 may be identical to the surrounding gas 310, or may be a different gas. For example, the second gas 316 and the surrounding gas 310 may both be air. Because the outflow 324 may include a velocity greater than that of the second gas 316 in the gaps between nozzles, the second gas 316 may become entrained, or mixed, with the outflow 324. In other words, the outflow 324 may cause the second gas 316 to be drawn towards the substrate and/or polishing pad, further cooling the substrate and/or polishing pad.

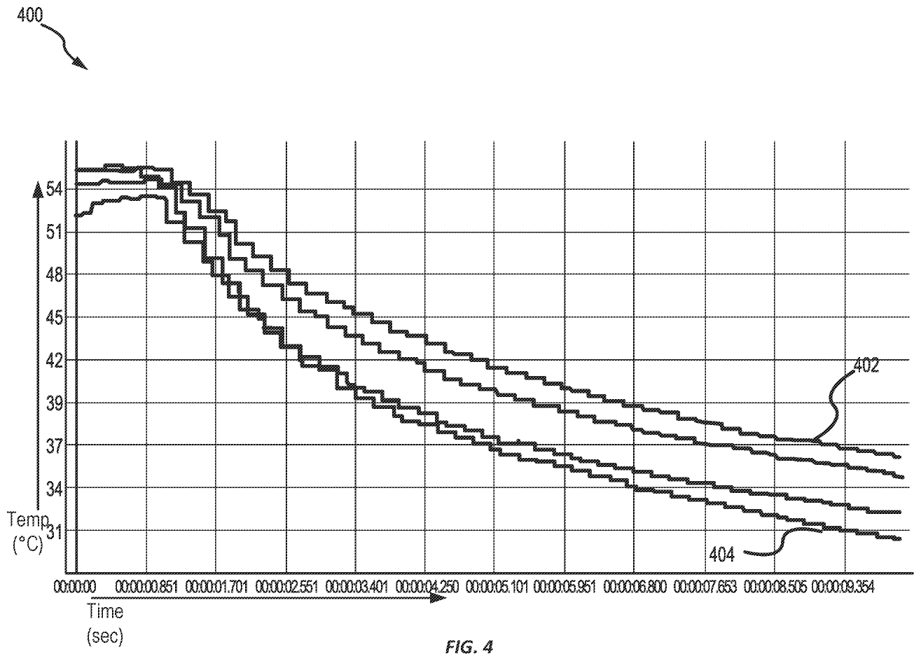

FIG. 4 illustrates a graph 400 of a temperature versus time of a polishing pad, according to certain embodiments. The graph 400 may illustrate the performance of traditional cooling systems and the performance of cooling systems as described herein. For example, a traditional cooling system may include a plurality of nozzles in an enclosed arm. Thus, the nozzles of the traditional cooling system may only include a gas provided to the nozzles. In other words, the nozzles may be sealed, unable to access a gas within the chemical mechanical processing chamber unless the gas is provided to the nozzles. Furthermore, because the nozzles may be disposed in an enclosed arm, any gas between the nozzles may also be within the enclosed arm. Therefore, the gas between the nozzles may not be entrained in the outflow of the nozzles and directed toward a polishing pad and/or substrate.

A first line 402 may represent the performance of the traditional cooling systems. For example, at or around 9 seconds, the line 402 may indicate a temperature of about 37° C. A second line 404 may represent the performance of some of the cooling systems and techniques described herein (e.g., the gas cooling assembly 220 and/or the nozzle 300). In contrast to the first line 402, the second line 404 may indicate the temperature of about 37° C. is reached in or about 4 seconds. Thus, a time needed to reach the temperature of about 37° C. using the cooling systems and techniques described herein may be reached within about one-half of the time as compared to the traditional cooling systems. At 9 seconds, the second line 404 may indicate a temperature of about 32° C. Thus, the cooling systems and techniques described herein may cool the polishing pad and/or substrate more than what is possible using traditional cooling systems.

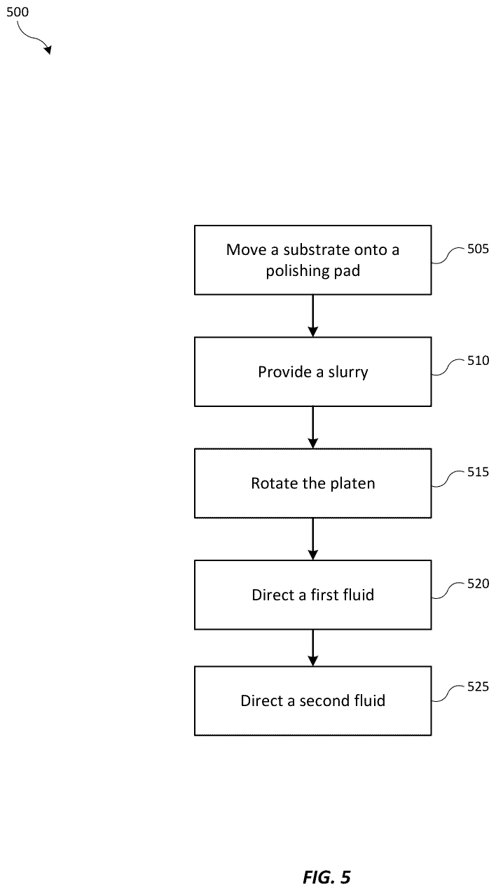

FIG. 5 illustrates a flowchart of a method 500 for cooling a polishing pad during a chemical mechanical polishing process, according to certain embodiments. The method 500 may be performed by any or all of the system described herein. For example, the method 500 may be performed by the system 100, the chamber 200, and/or the nozzle 300 in FIGS. 1, 2, and 3, respectively. Some of the steps of the method 500 may be performed in an order different than that shown in FIG. 5 and/or combined with other steps. In some embodiments, some steps of the method 500 may be skipped altogether.

At step 505, the method 500 may include moving a substrate onto a polishing pad supported by a platen within a chemical mechanical polishing chamber. The substrate may be moved via a carrier. The chemical mechanical polishing chamber may be similar to the system 100 in FIG. 1 and/or the chamber 200 in FIG. 2. The substrate may include one or more dies and/or semiconductor devices.

At step 510, the method may include providing a slurry to the polishing pad and/or the substrate. The slurry may include one or more compounds to perform chemical mechanical processing. For example, the slurry may include an aqueous solution in which abrasive particles may be suspended. The slurry may also include a pH adjuster and other chemically active components, such as an oxidizing agent, which may enable chemical mechanical polishing of the material surface of the substrate.

At step 515, the method may include rotating the platen such that the slurry and the polishing pad remove material from the substrate. The material may be moved according to a certain threshold, such that the substrate reaches a desired thickness.

At step 520, the method may include directing a first fluid from a nozzle towards the substrate and/or polishing pad. The first fluid may include a gas within the chemical mechanical processing chamber, such as the surrounding gas 310 in FIG. 3. The gas may be drawn into the nozzle passively (e.g., through a chamfer such as the chamfer 323) and/or actively, such via a fan. The first fluid may also include air or any other gas typically found within a chemical mechanical polishing chamber.

At step 525, the method 500 may include providing a second fluid to the nozzle such that the second fluid combines with the first fluid. The first and second fluids may combine in a main chamber of the nozzle (e.g., the main chamber 302). The second fluid may include a pressurized gas (e.g., nitrogen). The first and second fluids may combine with a gas surrounding the nozzle to form an outflow, directed towards the substrate and/or the polishing pad. The outflow may include an atomized fluid. The atomized fluid may include water.

In some embodiments, the outflow may cool the substrate and/or the polishing pad to a temperature of less than or about 37° C. The outflow may cool the substrate and/or the polishing pad to less than or about 37° C. in less than or about 10 seconds. In some embodiments, the substrate and/or the polishing pad may be cooled to less than or about 30° C.

In some embodiments, the nozzle may be attached to an arm within the chemical mechanical processing chamber. The arm may allow the gas to flow between the nozzle and an adjacent nozzle. A chamfer attached to the nozzle and/or the gas between the nozzle and the adjacent nozzle may increase an amount of outflow directed toward the substrate and/or polishing pad.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A chemical mechanical polishing chamber comprising:
a platen disposed within the chemical mechanical polishing chamber, the platen configured to support a polishing pad;
a slurry delivery arm configured to deliver a slurry to the polishing pad during a chemical mechanical polishing process;
an arm comprising one or more brackets, mechanically attached to an internal side of the chemical mechanical polishing chamber and positioned over the platen; and
a plurality of nozzles configured to deliver a gas to the polishing pad, the plurality of nozzles mechanically attached to the one or more brackets of the arm, each of the plurality of nozzles oriented such that an air gap is disposed between adjacent nozzles of the plurality of nozzles such that air may be pulled from the air gap and propelled with the gas towards the polishing pad.

2. The chemical mechanical polishing chamber of claim 1, further comprising a manifold disposed above the plurality of nozzles configured to provide air to the plurality of nozzles.

3. The chemical mechanical polishing chamber of claim 1, wherein the gas comprises nitrogen.

4. The chemical mechanical polishing chamber of claim 1, further comprising a manifold fluidly connected to each of the plurality of nozzles, the manifold configured to deliver a pressurized gas.

5. The chemical mechanical polishing chamber of claim 1, wherein each of the plurality of nozzles includes a chamfer configured to direct the gas into a respective nozzle to increase a volume of gas delivered to the polishing pad via the respective nozzle.

6. A gas amplifying nozzle for a chemical mechanical polishing chamber, the gas amplifying nozzle comprising:
a main chamber;
a first opening at a top of the gas amplifying nozzle, configured to allow air to enter the main chamber;
a chamfer attached to the top end of the gas amplifying nozzle, configured to direct air into the main chamber of the nozzle;
a side chamber configured to receive a pressurized gas and comprising an opening to provide the pressurized gas to the main chamber of the gas amplifying nozzle; and
a second opening at a bottom of the gas amplifying nozzle to direct an outflow comprising the air and pressurized gas from the main chamber to a platen to cool a polishing pad.

7. The gas amplifying nozzle of claim 6, wherein the pressurized gas is received via a manifold fluidly connected to the gas amplifying nozzle.

8. The gas amplifying nozzle of claim 6, wherein the outflow comprises water.

9. The gas amplifying nozzle of claim 6, wherein the air surrounding the gas amplifying nozzle is entrained in the outflow directed to the polishing pad.

10. The gas amplifying nozzle of claim 6, wherein the pressurized gas comprises nitrogen.

11. The gas amplifying nozzle of claim 6, wherein the second opening comprises a diameter of about 1 cm.

12. The gas amplifying nozzle of claim 6, wherein the air is directed into the chamfer, at least in part by a fan.

13. The gas amplifying nozzle of claim 6, wherein the pressurized gas increases a velocity of the outflow of the air and the pressurized gas from the main chamber.

14. A method, comprising:
moving a substrate via a carrier onto a polishing pad supported by a platen within a chemical mechanical polishing chamber;
providing a slurry to the polishing pad and/or the substrate, the slurry comprising one or more compounds to perform chemical mechanical processing;
rotating the platen such that the slurry and the polishing pad removes material from the substrate;
providing a first fluid to a nozzle; and
providing a second fluid to the nozzle such that the second fluid combines with the first fluid and a gas surrounding the nozzle to form an outflow, the outflow directed towards the substrate and/or polishing pad.

15. The method of claim 14, wherein the outflow comprises an atomized fluid comprising water.

16. The method of claim 14, wherein the outflow cools the substrate and/or the polishing pad to less than or about 37° C.

17. The method of claim 16, wherein the substrate and/or the polishing pad are cooled to less than or about 37° C. in less than or about 10 seconds.

18. The method of claim 14, wherein the second fluid comprises pressurized nitrogen.

19. The method of claim 14, wherein at least a portion of the first fluid is drawn into the nozzle from the chemical mechanical polishing chamber via a chamfer.

20. The method of claim 14, wherein the substrate and/or the polishing pad are cooled to less than or about 30° C.
